(19) United States
(12) Patent Application Publication
(10) Pub. No.: US 2024/0319285 A1
(43) Pub. Date: Sep. 26, 2024

(54) STORAGE BATTERY MANAGEMENT DEVICE, STORAGE BATTERY MANAGEMENT METHOD, AND RECORDING MEDIUM

(71) Applicants: KABUSHIKI KAISHA TOSHIBA, Tokyo (JP); TOSHIBA ENERGY SYSTEMS & SOLUTIONS CORPORATION, Kanagawa (JP)

(72) Inventors: Koji SASAKI, Inagi Tokyo (JP); Takahiro KASE, Kawasaki Kanagawa (JP); Takenori KOBAYASHI, Meguro Tokyo (JP); Kenji MITSUMOTO, Setagaya Tokyo (JP); Yoshihisa SUMIDA, Nakano Tokyo (JP); Koji TOBA, Tama Tokyo (JP)

(73) Assignees: KABUSHIKI KAISHA TOSHIBA, Tokyo (JP); TOSHIBA ENERGY SYSTEMS & SOLUTIONS CORPORATION, Kawasaki-shi Kanagawa (JP)

(21) Appl. No.: 18/261,220

(22) PCT Filed: Mar. 16, 2021
(86) PCT No.: PCT/JP2021/010523

§ 371 Date: Jul. 12, 2023

(51) Int. Cl. G01R 31/392; G01R 31/36; G01R 31/382; H01M 10/42; H01M 10/48; H02J 7/00

(52) U.S. Cl. CPC G01R 31/392; G01R 31/3648; G01R 31/382; H01M 10/425; H01M 10/482; H01M 2010/4271; H02J 7/005

(57) ABSTRACT

A storage battery management device according to the present embodiment includes a processor functioning as an acquisition unit, a deterioration prediction unit, a calculation unit, and a display control unit. The acquisition unit acquires parameters including charge/discharge power, a charge/discharge capacity, and SOC of the storage battery system of a storage battery system. The deterioration prediction unit predicts deterioration of the storage battery system on the basis of the acquired parameters. The calculation unit performs calculation relating to deterioration by multiple patterns with respect to one or more of parameters including the charge/discharge power, a C rate indicating a charging/discharging speed, etc., on the basis of a digital model and the predicted deterioration. The calculation unit specifies a pattern whose life extension effect is relatively high. The display control unit causes a display device to display the one or more parameters of the specified pattern.

### CROSS-REFERENCE TO RELATED APPLICATIONS

This application is national stage application of International Application No. PCT/JP2021/010523, filed on Mar. 16, 2021, which designates the United States, incorporated herein by reference.

### FIELD

Embodiments described herein relate generally to a storage battery management device, a storage battery management method, and a recording medium.

### BACKGROUND

In recent years, a storage battery system including a plurality of storage batteries has been used as, for example, a backup power supply or a power storage device by renewable energy power generation.

The storage battery gradually deteriorates due to various factors. Therefore, conventionally, an operator of a storage battery system diagnoses the life of the storage battery on a display screen of a storage battery management device, on the basis of the number of charge/discharge cycles of the storage battery, the result of capacity measurement at the time of maintenance, and so forth.

### BRIEF DESCRIPTION OF DRAWINGS

FIG. 1 is an overall configuration diagram illustrating an outline of a storage battery system of a first embodiment.

FIG. 2 is a configuration block diagram of a cell module and so forth of the first embodiment.

FIG. 3 is a configuration block diagram of a host control device according to the first embodiment.

FIG. 4 is a functional configuration block diagram of a control unit of the host control device according to the first embodiment.

FIG. 5 is an explanatory diagram illustrating an outline of processing of the host control device according to the first embodiment.

FIG. 6 is a graph schematically illustrating a state of a temporal change of a frequency of power at the time of suppressing fluctuation in the first embodiment.

FIG. 7 is a flowchart illustrating the processing of the host control device according to the first embodiment.

FIG. 8 is an explanatory diagram illustrating an outline of processing of a host control device according to the second embodiment.

FIG. 9 is a flowchart illustrating processing of the host control device according to the second embodiment.

FIG. 10 is an explanatory diagram illustrating an outline of processing of the host control device and so forth of a third embodiment.

### DETAILED DESCRIPTION

A storage battery management device including a hardware processor connected to a memory. The hardware processor is configured to function as an acquisition unit, a deterioration prediction unit, a calculation unit, and a display control unit. The acquisition unit acquires charge/discharge power, a charge/discharge capacity, and a State of Charge (SOC) of the storage battery system, as current operation state data of a storage battery system including a plurality of storage batteries. The deterioration prediction unit predicts deterioration of the storage battery system on the basis of the charge/discharge power, the charge/discharge capacity, and the SOC. The calculation unit performs calculation relating to deterioration by multiple patterns with respect to at least one or more of parameters including the charge/discharge power, a C rate indicating a charging/discharging speed, SOC upper and lower limit values, a standby SOC value indicating an SOC value during standby, and frequency upper and lower limit values. The calculation is performed on the basis of a digital model and the deterioration of the storage battery system predicted by the deterioration prediction unit. The digital model is capable of reproducing operation of the storage battery system in a simulative manner. The calculation unit specifies a pattern whose life extension effect is relatively high. The display control unit causes a display device to display the one or more parameters of the pattern, whose life extension effect is relatively high, specified by the calculation unit.

Hereinafter, embodiments (first to third embodiments) of a storage battery management device, a storage battery management method, and a program of the present invention will be described with reference to the drawings.

### First Embodiment

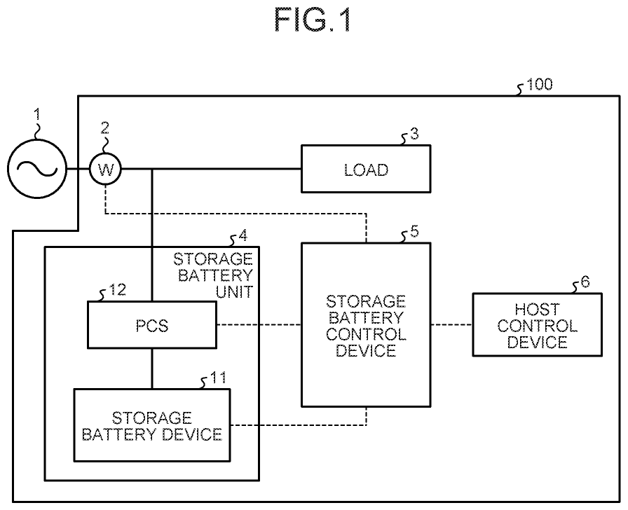

FIG. 1 is an overall configuration diagram illustrating an outline of a storage battery system 100 according to a first embodiment. For example, as illustrated in FIG. 1, the storage battery system 100 includes a power meter 2, a storage battery unit 4, a storage battery control device 5, and a host control device 6 (storage battery management device). Note that the configuration of the storage battery system 100 is not limited to this, and the configuration of individual devices constituting the storage battery system 100 is also not limited to the following.

A commercial power supply 1 supplies commercial power. The power meter 2 measures power supplied from the commercial power supply 1. A load 3 is a device that consumes the power.

The storage battery unit 4 charges the power of the commercial power supply 1 on the basis of a measurement result of the power meter 2, or discharges the power to supply the power to the load 3 when the power supply from the commercial power supply 1 is stopped.

The storage battery control device 5 performs local control of the storage battery unit 4. The host control device 6 performs remote control or the like of the storage battery control device 5.

In the above configuration, the load 3 normally operates by receiving power supply from the commercial power supply 1, and operates by receiving power supply from the storage battery unit 4 when the power supply from the commercial power supply 1 is stopped.

The storage battery unit 4 includes a storage battery device 11 that stores power, and a power conditioning system (PCS) 12 that performs operation of converting DC power supplied from the storage battery device 11 into AC power having a desired power quality, operation of supplying the AC power to a load, etc.

The storage battery device 11 includes a plurality of battery board units, a battery terminal board, and so forth. Each battery board includes a plurality of cell modules, a plurality of CMUs provided in each cell module, a service disconnect provided between the cell modules, a current sensor, a contactor, etc.

The battery board includes a BMU. A communication line of each CMU and the output line of the current sensor are connected to the BMU.

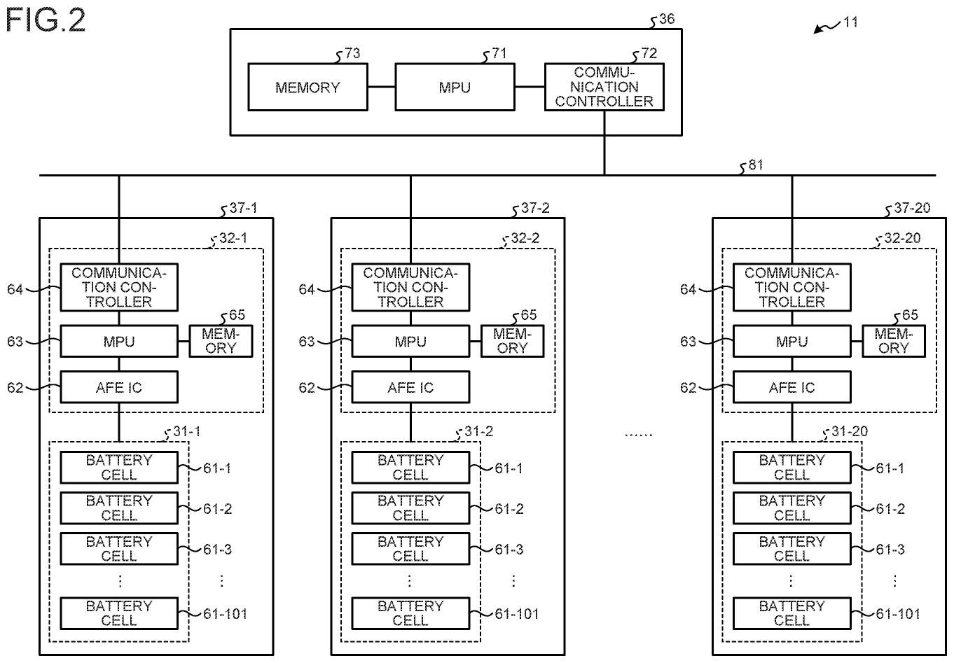

Here, detailed configurations of the cell module, the CMU, and the BMU will be described. FIG. 2 is a configuration block diagram of a cell module and so forth of the first embodiment. For example, as illustrated in FIG. 2, each of the cell modules 31-1 to 31-20 includes a plurality of battery cells 61-1 to 61-101 connected in series.

The CMUs 32-1 to 32-20 include an analog front end IC (AFE IC) 62 for measuring the voltage of the battery cells constituting the corresponding cell modules 31-1 to 31-20 and the temperature of a given place, an MPU 63 for controlling all corresponding CMUs 32-1 to 32-20, a communication controller 64 conforming to the controller area network (CAN) standard for performing communications with the BMU 36 via a CAN 81, and a memory 65 for storing voltage data and temperature data corresponding to the voltage of each cell.

In the following description, cell modules 31-1 to 31-20 and corresponding CMUs 32-1 to 32-20 are collectively referred to as storage battery modules 37-1 to 37-20. For instance, a combination of the cell module 31-1 and the corresponding CMU 32-1 is referred to as a storage battery module 37-1. Hereinafter, the storage battery modules 37-1 to 37-20 are also simply referred to as the storage battery module 37 or a storage battery unless otherwise distinguished.

In addition, the BMU 36 includes an MPU 71 that controls the entire BMU 36, a communication controller 72 conforming to the CAN standard for performing CAN communication with the CMUs 32-1 to 32-20, and a memory 73 that stores voltage data and temperature data transmitted from the CMUs 32-1 to 32-20.

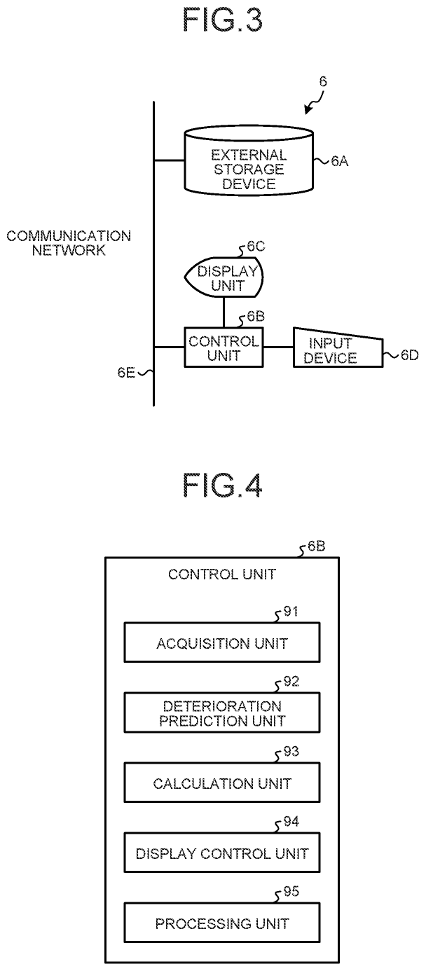

FIG. 3 is a configuration block diagram of the host control device 6 according to the first embodiment. The host control device 6 is configured as a computer device, and includes, for example, as illustrated in FIG. 3, an external storage device 6A, a control unit 6B that controls the entire host control device 6, a display unit 6C that displays various types of information to the operator, an input device 6D for the operator to input various types of information, and a communication network 6E for performing communication between the control unit 6B and the external storage device 6A and between the control unit 6B and an external device such as the storage battery control device 5.

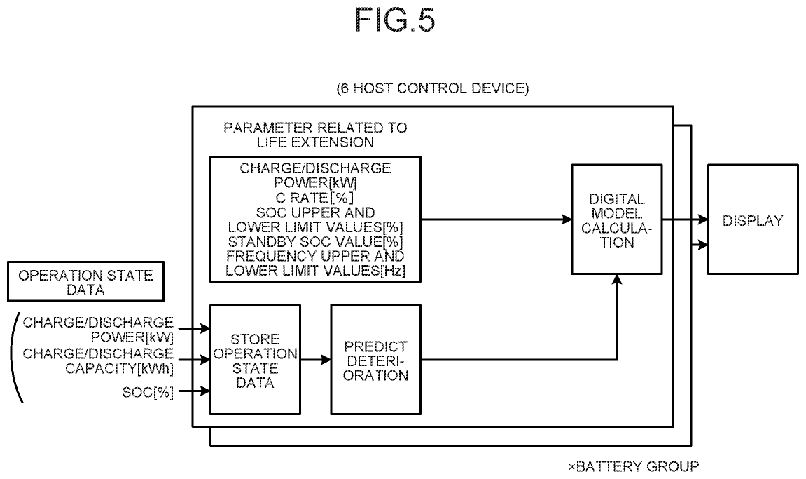

FIG. 4 is a functional configuration block diagram of the control unit 6B of the host control device 6 of the first embodiment. As illustrated in FIG. 4, the control unit 6B includes, as a functional configuration, an acquisition unit 91, a deterioration prediction unit 92, a calculation unit 93, a display control unit 94, and a processing unit 95. In the following description, FIG. 5 is also referred to. FIG. 5 is an explanatory diagram illustrating an outline of processing of the host control device 6 according to the first embodiment.

The acquisition unit 91 acquires various types of information from an external device (storage battery unit 4, storage battery control device 5, or the like). For example, the acquisition unit 91 acquires data of charge/discharge power [kW], charge/discharge capacity [kWh], and SOC [%] of the storage battery unit 4 as current operation state data of the storage battery system 100, and stores the acquired data in the external storage device 6A.

The deterioration prediction unit 92 predicts deterioration of the storage battery unit 4 on the basis of the charge/discharge power [kW], the charge/discharge capacity [kWh], and the SOC [%].

The calculation unit 93 executes various types of calculation processing on the basis of various types of information. For example, on the basis of a digital model (for example, a simulator program, an equivalent circuit, or the like) that can reproduce the operation of the storage battery system 100 in a simulative manner, and a deterioration prediction result by the deterioration prediction unit 92, the calculation unit 93 performs a calculation related to deterioration by multiple patterns with respect to at least one or more of the charge/discharge power [kW], a C rate indicating a charging/discharging speed, SOC upper and lower limit values [%], a standby SOC value [%] indicating an SOC value during standby, and frequency upper and lower limit values [Hz] as parameters related to life extension, and then specifies a pattern whose life extension effect is relatively high. In the following description, it is assumed that all the above-described five parameters are used.

The calculation unit 93 specifies parameter values of the pattern whose life extension effect is relatively high and causes the display control unit 94 to display the parameter values, whereby the operation support regarding the life extension of the storage battery unit 4 can be performed for the operator. The operation support refers to, for example, displaying the charge/discharge power [kW], the C rate, the SOC upper and lower limit values [%], the standby SOC value [%], and the frequency upper and lower limit values [Hz] contributing to the life extension, and/or adjusting the control using a given constraint condition or a given objective function with respect to the control of the charge/discharge power [kW] given by the operator.

With regard to a method of extending the life, for example, suppression of the maximum output of the storage battery unit 4, limitation of the SOC range, setting of an operation temperature constraint, setting of a rest time, and so forth can be considered as a method common to the cases of frequency adjustment, supply and demand balance adjustment, peak shift, and so forth.

Moreover, in the case of frequency adjustment, a decrease in sensitivity with respect to the frequency, an extension of a dead zone, and so forth can be considered. In the case of the supply and demand balance adjustment, for example, relaxation of a run plate (output change rate) is considered. In addition, in the case of the peak shift, for example, an increase in the threshold of the peak power, a decrease in the discharge rate, and so forth are considered.

The display control unit 94 executes control for causing the display unit 6C to display various types of information. The display control unit 94 causes the display unit 6C to display, for example, parameters of a pattern, whose life extension effect is relatively high, specified by the calculation unit 93.

The calculation unit 93 may perform the above-described calculation by further using a given constraint condition set by the operator. As the constraint conditions, for example, the following (1) to (4) are conceivable.
(1) Constraint condition for causing no deterioration in performance of the storage battery unit 4
(2) Constraint conditions for causing no reduction of revenue obtained by fluctuation suppression
(3) Constraint condition for causing no reduction in amount of peak shift during peak shift
(4) Constraint condition on operation time (for example, prohibition of use at night)

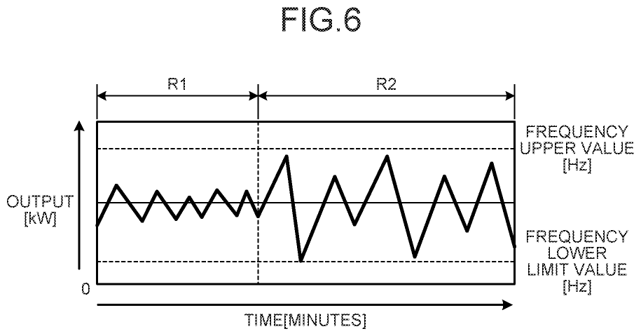

An example of (1) will be described with reference to FIG. 6. FIG. 6 is a graph schematically illustrating a state of a temporal change of the frequency of the power at the time of suppressing the fluctuation in the first embodiment. As an example of the constraint condition for causing no deterioration in performance of the storage battery unit 4, a case of causing frequency to fall within a prescribed standard will be described.

In FIG. 6, the range between the frequency lower limit value and the frequency upper limit value is within the standard. In order to keep the frequency within the standard, in suppressing the frequency fluctuation, as illustrated in a region R1, the frequency fluctuation may be suppressed to the minimum as in the conventional technique. However, as illustrated in a region R2, it is also possible to widen a dead zone such that the storage battery operates within the range in which the fluctuation falls within the frequency standard. In this way, the operation of the storage battery unit 4 can be minimized to contribute to life extension.

Returning to FIGS. 4 and 5, the calculation unit 93 may perform the calculation by further using a given objective function defined so as to prioritize the revenue from the storage battery system 100 over the life extension effect of the storage battery unit 4.

Specifically, the following objective function is used, for example. The revenue obtained by the operation of the storage battery system 100 is denoted as B. In addition, the cost required by deterioration, replacement, and addition of the storage battery is denoted as C. Moreover, a is a constant satisfying 0<α<1. Then, an objective function T can be expressed by the following Equation (1).

$$T = α \times B - ( 1 - α ) \times C \qquad ( 1 )$$

Each parameter is determined so as to maximize the objective function T. Then, due to a difference in the operator's situation, there is a desire to prioritize the revenue over the life extension, or a desire to prioritize the life extension for long-term management over the revenue, etc.

Specifically, for example, in a case where the revenue and the cost are treated equally, α=0.5 may be set.

In a case of responding to the desire to prioritize the revenue, 0.5<α<1 may be satisfied.

In a case of responding to the desire to prioritize the life extension, 0<α<0.5 may be satisfied.

In this manner, by determining a in accordance with the priorities of the revenue and the cost, it is possible to determine the parameters corresponding to the intention of the operator.

Note that, as the revenue obtained by the operation of the storage battery system 100, the following (11) to (13) can be considered, for example.
(11) In the case of frequency adjustment, a consideration for the frequency adjustment
(12) In the case of supply and demand balance adjustment, a consideration for the supply and demand balance adjustment with respect to fluctuation of power generation amount by renewable energy generator and demand fluctuation
(13) In the case of the peak shift, a difference in power charge between the peak time and the off-peak time, etc.

In addition, the calculation unit 93 may perform the calculation by further using an objective function defined to select a storage battery to be used. The storage battery is selected to minimize a total cost in which each cost is calculated by converting the deterioration of each of the storage batteries into cost.

In addition, the calculation unit 93 may determine whether the deterioration of the storage battery unit 4 progresses faster than a given speed when the current operation of the storage battery system 100 is continued. Then, in response to determination that the deterioration of the storage battery unit 4 progresses faster than the given speed, the display control unit 94 causes the display unit 6C to display alarm information (alarm).

In addition, the calculation unit 93 may periodically estimate the deterioration state of the storage battery on the basis of data including the temperature at the time of operating the storage battery. When it is estimated that the deterioration state has reached the given deterioration state threshold, the display control unit 94 causes the display unit 6C to display information for making notification of the deterioration of the storage battery. In general, since the deterioration rate of the storage battery increases as the temperature of the storage battery increases, it is effective to use the temperature of the storage battery for estimating the deterioration state of the storage battery unit 4. Information other than the temperature of the storage battery may be used to estimate the deterioration state of the storage battery unit 4.

The processing unit 95 executes processing other than the processing performed by each of the units 91 to 94.

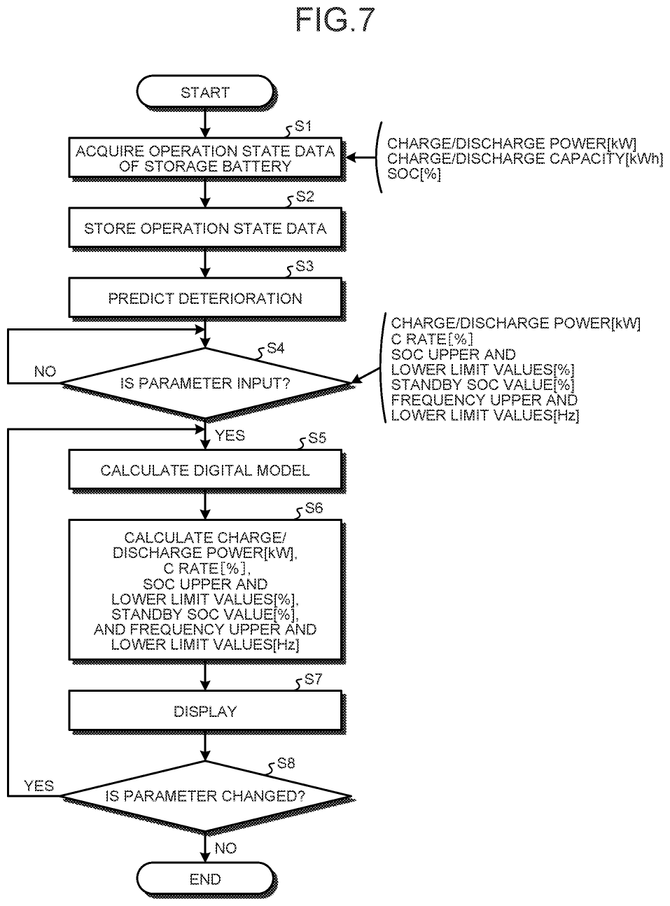

FIG. 7 is a flowchart illustrating processing of the host control device 6 according to the first embodiment. In Step S1, the acquisition unit 91 acquires data of the charge/discharge power [kW], the charge/discharge capacity [kWh], and the SOC [%] of the storage battery unit 4 as current operation state data of the storage battery system 100. In Step S2, the acquisition unit 91 stores the data in the external storage device 6A.

Next, in Step S3, the deterioration prediction unit 92 predicts the deterioration of the storage battery unit 4 on the basis of the charge/discharge power [kW], the charge/discharge capacity [kWh], and the SOC [%].

Next, in Step S4, the acquisition unit 91 determines whether the parameters (charge/discharge power [kW], C rate, SOC upper and lower limit values [%], standby SOC value [%], and frequency upper and lower limit values [Hz]) has been input. In a case of Yes, the step proceeds to Step S5. In a case of No, the process returns to Step S4.

In Step S5, on the basis of the digital model and the deterioration prediction result in Step S3, the calculation unit 93 performs an arithmetic operation related to deterioration by multiple patterns for the charge/discharge power [kW], the C rate, the SOC upper and lower limit values [%], the standby SOC value [%], and the frequency upper and lower limit values [Hz] as parameters related to life extension.

Next, in Step S6, as a result of the digital model calculation in Step S5, the calculation unit 93 calculates the charge/discharge power [kW], the C rate, the SOC upper and lower limit values [%], the standby SOC value [%], and the frequency upper and lower limit values [Hz] of the pattern whose life extension effect is relatively high.

Next, in Step S7, the display control unit 94 causes the display unit 6C to display the parameters of the pattern, whose life extension effect is relatively high, calculated in Step S6.

Next, in Step S8, the calculation unit 93 determines whether the parameters (charge/discharge power [kW], C rate, SOC upper and lower limit values [%], standby SOC value [%], and frequency upper and lower limit values [Hz]) has been changed. In a case of Yes, the step returns to Step S5, and in a case of No, the step ends.

As described above, with the host control device 6 of the first embodiment, it is possible to perform the operation support related to the life extension using the current operation state data of the storage battery system 100 and so forth. Specifically, as a result of the digital model calculation, it is possible to calculate and display parameters (charge/discharge power [kW], C rate, SOC upper and lower limit values [%], standby SOC value [%], and frequency upper and lower limit values [Hz]) of a pattern whose life extension effect is relatively high.

The life of the storage battery system 100 may greatly change depending on the operation method thereof, whereas the operator can easily extend the life of the storage battery system 100 by the operation support implemented by the digital model calculation described above.

Moreover, it is possible to calculate and display the parameters of the pattern corresponding to the intention of the operator by using the above-described constraint condition and objective function. Specifically, for example, it is possible to calculate and display parameters reflecting how much priority is given to which of the revenue obtained by the operation of the storage battery system 100 and the cost required by deterioration, replacement, and addition of the storage battery.

In addition, by displaying the alarm information when the deterioration rate of the storage battery unit 4 is high, the operator can quickly take necessary measures.

In addition, by periodically estimating the deterioration state of the storage battery and giving notification to the operator when the deterioration is estimated, the operator can quickly take necessary measures.

In addition, as illustrated in FIG. 6, when the frequency falls within the standard, in the frequency fluctuation suppression, instead of minimizing the frequency fluctuation as in the conventional technique as illustrated in the region R1, the dead zone can be widened as illustrated in the region R2, and the storage battery can be operated in a range in which the fluctuation falls within the standard of the frequency. In this way, the operation of the storage battery unit 4 can be minimized to contribute to life extension.

### Second Embodiment

Next, a second embodiment will be described. The same matters as those in the first embodiment will not be described repeatedly as appropriate. The second embodiment is different from the first embodiment in that, artificial intelligence (AI) learning is used.

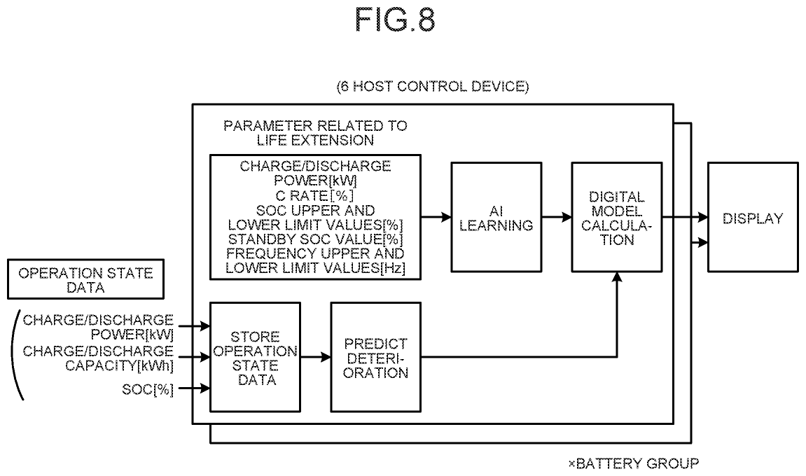

FIG. 8 is an explanatory diagram illustrating an outline of processing of a host control device 6 according to the second embodiment. The calculation unit 93 learns weighting for each parameter (charge/discharge power [kW], C rate, SOC upper and lower limit values [%], standby SOC value [%], and frequency upper and lower limit values [Hz]) by using AI before executing processing using the digital model.

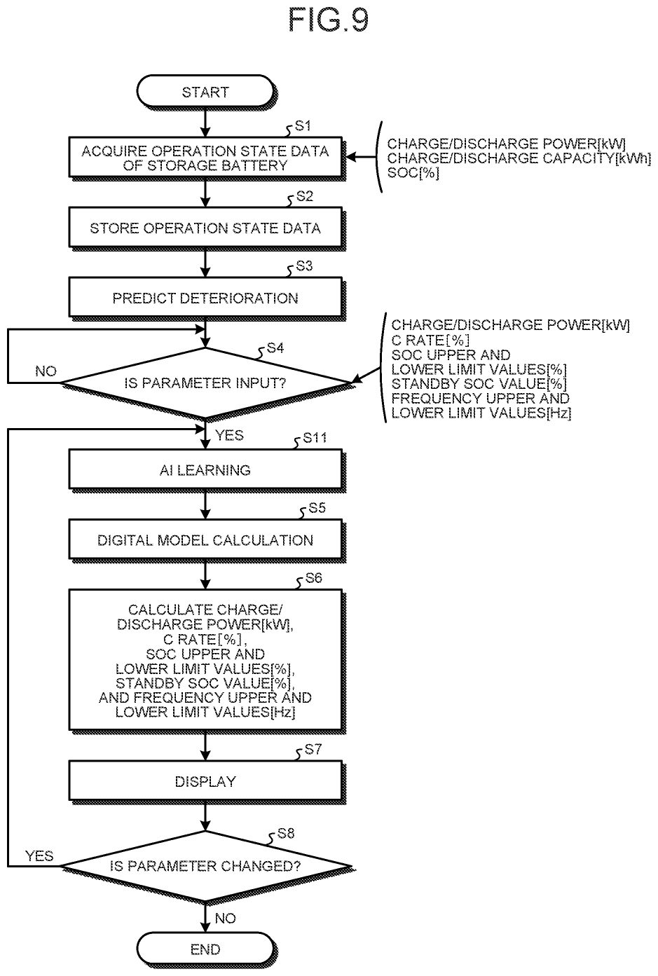

FIG. 9 is a flowchart illustrating processing of the host control device 6 according to the second embodiment. This flowchart is different from the flowchart of FIG. 7 of the first embodiment in that, Step S11 is inserted before Step S5.

In a case of Yes in Step S4, the calculation unit 93 learns in Step S11 weighting for each parameter using AI before executing processing using the digital model.

Thereafter, in Step S5, the calculation unit 93 performs an arithmetic operation related to deterioration for the parameters by multiple patterns on the basis of the digital model, the deterioration prediction result in Step S3, and a result of the AI learning in Step S11.

As described above, with the host control device 6 of the second embodiment, the calculation accuracy can be further improved by determining the weighting for each parameter (charge/discharge power [kW], C rate, SOC upper and lower limit values [%], standby SOC value [%], and frequency upper and lower limit values [Hz]) by AI learning, and thereby the life extension effect can be further improved.

### Third Embodiment

Next, a third embodiment will be described. The same matters as those in the first embodiment will not be described repeatedly as appropriate. In the third embodiment, the digital model calculation is performed by a cloud computing system (not illustrated, and hereinafter, it is also simply referred to as “cloud”).

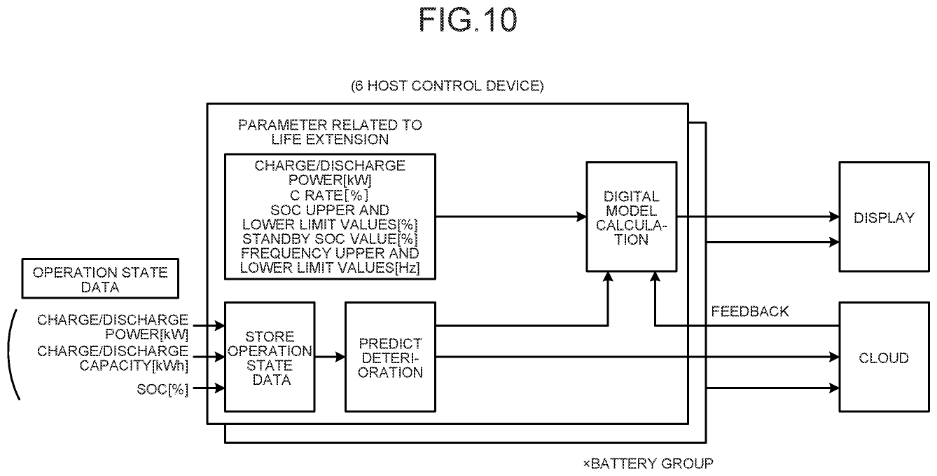

FIG. 10 is an explanatory diagram illustrating an outline of processing of a host control device 6 and so forth of the third embodiment. The calculation unit 93 (FIG. 4) is a functional object provided in the cloud computing system. Specifically, the calculation unit 93 in the cloud collects operation state data, deterioration prediction results, and so forth relative to the storage battery group. The calculation unit 93 then performs digital model calculation to calculate parameters whose life extension effect is relatively high as a calculation result, and feeds back the parameters to each storage battery group. Since the processing flow itself is similar to that in FIG. 7, a detailed description thereof will be omitted.

As described above, with the host control device 6 of the third embodiment, by performing the digital model calculation by the cloud, for example, it is possible to easily cope with a case where the calculation amount is large.

The host control device 6 functioning as the storage battery management device of the present embodiment can have a hardware configuration using a normal computer including a control device such as a central processing unit (CPU), a storage device such as a read only memory (ROM) and a random access memory (RAM), an external storage device such as a hard disk drive (HDD) and a compact disc (CD) drive device, a display device such as a display unit, an input device such as a keyboard and a mouse, and so forth.

Therefore, the program executed by the host control device 6 functioning as the storage battery management device of the present embodiment can be provided by being recorded in a computer-readable recording medium such as a CD-ROM, a flexible disk (FD), a CD-R, and a digital versatile disk (DVD) as a file in an installable format or an executable format.

In addition, the program may be stored on a computer connected to a network such as the Internet and provided by being downloaded via the network. Moreover, the program may be provided or distributed via a network such as the Internet.

In addition, the program may be provided by being incorporated in a ROM or the like in advance.

Although embodiments of the present invention have been described, the embodiments have been presented as examples, and are not intended to limit the scope of the invention. This novel embodiment can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

For example, the storage battery management device may be implemented by a computer device other than the host control device 6.

In addition, the AI learning and the cloud may be simultaneously implemented by combining the second/third embodiments with the first embodiment.

1. A storage battery management device comprising a hardware processor connected to a memory, the hardware processor being configured to function as:
an acquisition unit to acquire charge/discharge power, a charge/discharge capacity, and a State of Charge (SOC) of the storage battery system, as current operation state data of a storage battery system including a plurality of storage batteries;
a deterioration prediction unit to predict deterioration of the storage battery system on the basis of the charge/discharge power, the charge/discharge capacity, and the SOC;
a calculation unit to
perform calculation relating to deterioration by multiple patterns with respect to at least one or more of parameters including the charge/discharge power, a C rate indicating a charging/discharging speed, SOC upper and lower limit values, a standby SOC value indicating an SOC value during standby, and frequency upper and lower limit values, the calculation being performed on the basis of a digital model and a the deterioration of the storage battery system predicted by the deterioration prediction unit, the digital model being capable of reproducing operation of the storage battery system in a simulative manner, and
specify a pattern whose life extension effect is relatively high; and
a display control unit to cause a display device to display the one or more parameters of the pattern, whose life extension effect is relatively high, specified by the calculation unit.

2. The storage battery management device according to claim 1, wherein the calculation unit performs the calculation by further using a given constraint condition set by a user.

3. The storage battery management device according to claim 1, wherein the calculation unit performs the calculation by further using a given objective function defined to prioritize revenue from the storage battery system over the life extension effect of the storage battery system.

4. The storage battery management device according to claim 2, wherein the given constraint condition is a constraint condition for causing no deterioration in performance of the storage battery system.

5. The storage battery management device according to claim 1, wherein the calculation unit performs the calculation by further using an objective function defined to select a storage battery to be used, the storage battery being selected to minimize a total cost in which each cost is calculated by converting deterioration of each of the storage batteries into cost.

6. The storage battery management device according to claim 1, wherein the calculation unit is a functional object provided in a cloud computing system.

7. The storage battery management device according to claim 1, wherein
the calculation unit determines whether deterioration of the storage battery system progresses faster than a given speed when the current operation of the storage battery system is continued, and
the display control unit causes the display device to display alarm information in response to determination that the deterioration of the storage battery system progresses faster than the given speed.

8. The storage battery management device according to claim 1, wherein
the calculation unit periodically estimates a deterioration state of the storage battery on the basis of data including a temperature during operation of the storage battery, and,
when the deterioration state reaches a given deterioration state threshold, the display control unit causes the display device to display information for making notification of the deterioration of the storage battery.

9. The storage battery management device according to claim 1, wherein the calculation unit learns weighting for each of the parameters by using artificial intelligence (AI) before processing using the digital model.

10. A storage battery management method comprising:
acquiring charge/discharge power, a charge/discharge capacity, and a State of Charge (SOC) of the storage battery system, as current operation state data of a storage battery system including a plurality of storage batteries;
predicting deterioration of the storage battery system on the basis of the charge/discharge power, the charge/discharge capacity, and the SOC;
performing calculation relating to deterioration by multiple patterns with respect to at least one or more of parameters including the charge/discharge power, a C rate indicating a charging/discharging speed, SOC upper and lower limit values, a standby SOC value indicating an SOC value during standby, and frequency upper and lower limit values, the calculation being performed on the basis of a digital model and the deterioration of the storage battery system predicted by the predicting, the digital model being capable of reproducing operation of the storage battery system in a simulative manner;
specifying a pattern whose life extension effect is relatively high; and
causing a display device to display the one or more parameters of the pattern, whose life extension effect is relatively high, specified by the specifying.

11. A non-transitory computer-readable recording medium on which programmed instructions are recorded, the instructions causing a computer to execute processing, the processing comprising:
acquiring charge/discharge power, a charge/discharge capacity, and a State of Charge (SOC) of the storage battery system, as current operation state data of a storage battery system including a plurality of storage batteries;
predicting deterioration of the storage battery system on the basis of the charge/discharge power, the charge/discharge capacity, and the SOC;
performing calculation relating to deterioration by multiple patterns with respect to at least one or more of parameters including the charge/discharge power, a C rate indicating a charging/discharging speed, SOC upper and lower limit values, a standby SOC value indicating an SOC value during standby, and frequency upper and lower limit values, the calculation being performed on the basis of a digital model and the deterioration of the storage battery system predicted by the predicting, the digital model being capable of reproducing operation of the storage battery system in a simulative manner;
specifying a pattern whose life extension effect is relatively high; and
causing a display device to display the one or more parameters of the pattern, whose life extension effect is relatively high, specified by the specifying.
